(19) United States
(12) Patent Application Publication
(10) Pub. No.: US 2022/0165979 A1
(43) Pub. Date: May 26, 2022

(54) ORGANIC LIGHT-EMITTING DISPLAY PANEL AND MANUFACTURING METHOD THEREOF

(71) Applicant: SeeYA Optronics Co., Ltd., Shanghai (CN)

(72) Inventor: Zhongshou HUANG, Shanghai (CN)

(73) Assignee: SeeYA Optronics Co., Ltd., Shanghai (CN)

(21) Appl. No.: 17/378,498

(22) Filed: Jul. 16, 2021

(30) Foreign Application Priority Data
Nov. 26, 2020 (CN) 202011347790.2

(51) Int. Cl. H01L 51/52; H01L 27/32; H01L 51/00; H01L 51/56

(52) U.S. Cl. CPC H01L 51/5225; H01L 27/3246; H01L 51/0021; H01L 2251/558; H01L 51/56; H01L 2227/323; H01L 51/5281

(57) ABSTRACT

An organic light-entitling display panel and a manufacturing method thereof are provided. The organic light-emitting display panel includes a substrate, a first electrode, a pixel definition layer with openings to expose a part of the first electrode. A fence structure, including a plurality of fences arranged in parallel to each other and to the substrate, is formed on the first electrode within the openings. A light-emitting functional layer and a second electrode are deposited in sequence on the fence structure by using a slanted evaporation method that results in a thickness distribution of the second electrode that the thickness on the top of the fences is greater than the thickness between each fences.

### CROSS-REFERENCE TO RELATED APPLICATIONS

The present application claims priority to Chinese Patent Application No. 202011347790.2, filed on Nov. 26, 2020, the content of which is incorporated herein by reference in its entirety.

### TECHNICAL FIELD

The present disclosure relates to the field of display technology, and in particular, to an organic light-emitting display panel and a method for manufacturing the organic light-emitting display panel.

### BACKGROUND

With the development of Organic Light Emitting Diode (OLED) display technology and expansion of large-scale manufacturing industry thereof, OLED displays have become a mainstream of mobile displays, and occupied a considerable market share of medium-sized PC monitors and even large-sized TV displays. However, as the OLED display technology is gradually applied in some special display application fields, such as Augment Reality (AR) and Virtual Reality (VR) display fields, some restrictions of the original device structure on display performance have become more apparent.

Taking the micro display in AR and VR glasses as an example, features including light weight, thin and compact physical dimensions, and at the same time higher image spatial resolution, lower power consumption and higher brightness, are becoming increasingly important. However, the miniaturization in geometric factors and pursing higher display performance inevitably results in tricky challenges to deal with apparently conflict requirements in display designs and fabrications. The display performances, such as brightness, color gamut and power consumption will be significantly degraded with display miniaturization in general, unless new device structures and manufacturing method thereof are developed and implemented.

### SUMMARY

In view of this, the embodiments of the present disclosure provide an organic light-emitting display panel and a method for manufacturing the organic light-emitting display panel, which can effectively increase luminous flux of light emitted from the organic light-emitting display panel while preventing significant increase in the square resistance of a cathode layer.

In a first aspect, an embodiment of the present disclosure provides an organic light-emitting display panel that includes a substrate and a light-emitting device disposed on the substrate. The light-emitting device includes: a first electrode; a pixel definition layer with a plurality of openings located on the first electrode facing away from the substrate; a fence structure located in the plurality of openings and facing away from the substrate; a light-emitting functional layer; and a second electrode formed in sequence on the fence structure. The fence structure includes a plurality of fences and trenches arranged in parallel to the substrate. The thickness of the second electrode on the top of the fences is larger than the thickness of the second electrode between the fences.

In a second aspect, an embodiment of the present disclosure provides a method for manufacturing an organic light-emitting display panel. The method includes: disposing the substrate overlaid by the first electrode, the pixel definition layer and the fence structure on a supporting stage inside a vapor deposition chamber; providing at least one crucible or sputtering target containing a raw material for forming the second electrode in the vapor deposition chamber; and forming the second electrode on the substrate by heating the at least one crucible or by plasma bombarding one sputtering target. During said forming the second electrode, a direction along which the raw material for forming the second electrode fly towards the substrate is in an oblique angle with respect to the substrate, and the oblique angle is smaller than 90 degrees.

The organic light-emitting display panel and the method for manufacturing the organic light-emitting display panel according to the present disclosure at least have the following beneficial effects.

In the embodiments of the present disclosure, the film thickness of the second electrode, i.e. a cathode, between the fences is relatively small, so that an absorption of this part of the second electrode to light emitted from the light-emitting layer is thus reduced. In particular, when the film thickness of this part of the second electrode is thinned to a certain extent, this part of the second electrode will have the optical properties of a nano film, so that the light transmittance of this part of the second electrode will be greatly increased. Therefore, the loss of overall luminous flux of the light emitted from the display panel can be significantly reduced by thinning a part of the second electrode. That is, the light output capacity of the display panel is improved. When an intensity of the light carrying image information emitted from the display panel increases, the brightness of the image displayed on the display panel and the color gamut increase correspondingly, thereby optimizing the image quality.

Moreover, compared to the arrangement in which the thickness of the entire second electrode is reduced, in the embodiments of the present disclosure, only the part of the second electrode at the side walls of the fences or at the bottoms of the trenches is thinned. Therefore, the square resistance of the second electrode will be only slightly increased or remain unchanged as compared with the prior art, thereby avoiding excessively large signal voltage drop caused by large increase in the square resistance and deterioration of the brightness uniformity and color display accuracy of the displayed image.

### BRIEF DESCRIPTION OF DRAWINGS

In order to clearly illustrate technical solutions in embodiments of the present disclosure, the accompanying drawings used in the embodiments are briefly described as follows. It should be noted that the drawings described are merely some of the embodiments of the present disclosure, and those skilled in the art can make extensions and modifications from the principles and concepts disclosed in the embodiments of the present disclosure to conceive other similar structures, and all these structures conceived based on the principles and concepts disclosed in the embodiments of the present disclosure shall fall into the scope of the present disclosure.

FIG. 1 illustrates a sectional view in an X-Z plane of a subpixel in an OLED display panel in a related art;

FIG. 2 illustrates light reflections at two sides of a cathode layer in the related art;

FIG. 3 illustrates a sectional view of two adjacent subpixels in an X-Z plane of an OLED panel according to an embodiment of the present disclosure;

FIG. 4 illustrates a top view of a fence structure in an opening according to an embodiment of the present disclosure;

FIG. 5 illustrates a sectional view of a subpixel according to an embodiment of the present disclosure, indicating a thickness variation of the second electrode;

FIG. 6 illustrates another sectional view of a subpixel according to an embodiment of the present disclosure, indicating a thickness variation of the second electrode;

FIG. 7 illustrates a top view of another fence structure in an opening according to an embodiment of the present disclosure;

FIG. 8 illustrates a sectional view of a fence structure according to an embodiment of the present disclosure;

FIG. 9 illustrates a sectional view of an encapsulated subpixel according to an embodiment of the present disclosure;

FIG. 10 illustrates a sectional viewing indicating a polarization direction of a polarizer according to an embodiment of the present disclosure;

FIG. 11 illustrates a top plane view indicating a polarization direction of a polarizer according to an embodiment of the present disclosure;

FIG. 12 illustrates a sectional view of another fence structure according to an embodiment of the present disclosure;

FIG. 13 illustrates a flowchart of a manufacturing process of an OLED panel according to an embodiment of the present disclosure;

FIG. 14 illustrates an oblique vapor deposition process by rotating the substrate supporting stage according to an embodiment of the present disclosure;

FIG. 15 illustrates still another oblique vapor deposition process according to an embodiment of the present disclosure;

FIG. 16 illustrates a set-up of vet another oblique vapor deposition process according to an embodiment of the present disclosure; and

FIG. 17 illustrates a schematic structural diagram of a VR glass system using the OLED device according to an embodiment of the present disclosure.

### DESCRIPTION OF EMBODIMENTS

The technical solutions in the embodiments of the present disclosure are described in the following with reference to the accompanying drawings. It should be noted that the described embodiments are merely exemplary embodiments of the present disclosure, which shall not be interpreted as limiting the present disclosure. All other embodiments obtained by those skilled in the art based on the concepts and methods disclosed in the present disclosure shall fall within the scope of the present disclosure.

The terms used in the embodiments of the present disclosure are merely for the purpose of describing particular embodiments, but not intended to limit the present disclosure. Unless otherwise noted in the context, the singular form expressions prefixed with “a”, “an”, “the” and “said” used in the embodiments and appended claims of the present disclosure are also intended to represent plural form expressions thereof.

For example, a micro display used in the AR and VR glasses is illustrated in FIG. 1. FIG. 1 illustrates a sectional view in an X-Z plane of a subpixel in an OLED display panel in the related art. An OLED display panel in the AR, VR field is different from a structure using glass as a substrate in mobile phone and computer in that it commonly uses silicon as a substrate 100′, and structures such as pixel circuits, row scan circuits, signal driving circuits are integrated onto this silicon substrate, utilizing the advantages of a large-scale integrated circuit. A light-emitting device 200′, a first planarization layer 300′, a filter layer 400′, a second planarization layer 500′ and a cover plate 600′ are sequentially stacked up on the substrate 100′. The light-emitting device 200′ includes an anode 201′, a pixel definition layer 202′, a hole injection and transport layer 203′, a light-emitting layer 204′, an electron injection and transport layer 205′, and a cathode 206′ that are stacked up in sequence. Via a through hole 700′, the anode 201′ is electrically connected to a pixel circuit in the substrate 100′. The pixel definition layer 202′ has an opening 207′ that defines an effective light output region of the subpixel. A portion of the anode 201′ is exposed in the opening 207′, and a portion of the hole injection and transport layer 203′, a portion of the light-emitting layer 204′, a portion of the electron injection and transport layer 205′ and a portion of the cathode 206′ are recessed in the opening 207′. Moreover, an elevation angle of a side wall of the pixel definition layer 202′ is larger than 90°, so that the hole injection and transport layer 203′ may be discontinuous at the side wall.

When the OLED display panel with the above structure is driven to emit light, light emitted from the light-emitting layer 204′ is required to be transmitted through the layers having different optical properties and stacked on the light-emitting layer 204′ before being emitted into the air to become a light beam 800′ carrying image information. During a transmission process of the light, the light will be reflected at an interface between every two layers due to the difference in refractive index between the two layers, and may be absorbed in each layer, resulting in great loss of luminous flux, thereby adversely affecting light output capacity of the display panel.

In this regard, the applicant of the present disclosure has conducted in-depth researches and found that in the luminous flux loss caused by reflection and absorption, the interface reflection and internal absorption of light caused by the cathode 206′ are particularly serious.

In the prior art, the cathode 206′ is commonly formed by a metal material with stable chemical properties and a small work function in order to improve an electron injection efficiency. Currently, an alloy film of silver or aluminum is commonly used in the related art, e a Mg:Ag(10:1) alloy electrode with a work function of 3.7 eV, or a Li:Al(0.6% Li) alloy electrode with a work function of 3.2 eV.

When metallic silver or metallic aluminum is used, the formed cathode is usually an opaque metal film unless the film thickness is smaller than 50 nm. As an example of metallic silver, a complex part of a complex refractive index of metallic silver, i.e. an extinction coefficient k, is approximately 3.6. When yellow-green light with a wavelength λ of 550 nm is incident to metallic silver, an absorption coefficient a of metallic silver for the yellow-green light is 8.22×10⁵ cm⁻¹ according to a relationship formula between the absorption coefficient a and the extinction coefficient k: α=4 πk/λ. A metallic silver film with a thickness of 80 nm approximately absorbs 99% of the incident light, and only when the thickness of the metallic silver film is reduced to 30 nm, the absorption of the incident light can be reduced to 91%.

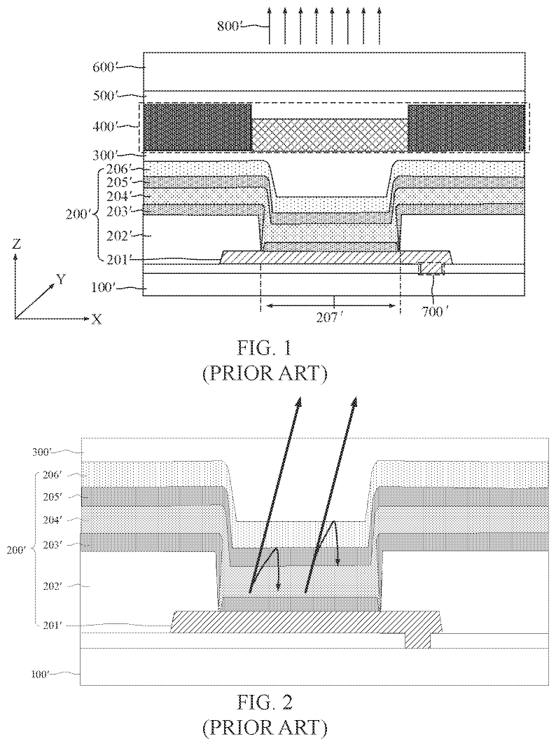

On the other hand, a real part of the complex refractive index of metallic silver, i.e. a refractive index, is approximately 0.2. In the display panel, the light-emitting layer 204′ and the electron injection and transport layer 205′ each has a refractive index of approximately 1.5, and the first planarization layer 300′ has a refractive index of approximately 1.45. With reference to FIG. 2, which illustrates light reflections at two sides of a cathode layer, approximately less than 12% of the light emitted from the light-emitting layer 204′ is extracted after the light is reflected by an interface between the electron injection and transport layer 205′ and the cathode 206′ and an interface between the cathode 206′ and the first planarization layer 300′, resulting in a relatively lower intensity of the light that finally enters the air and carries image information.

According to the properties of the metal film, when a thickness of the metal film is reduced to a nanometer level below 20 nm, a physical mechanism of resonance absorption and reflection in the metal lattice and atoms related to the wavelength of light is no longer applicable, the optical properties of nano metal will became more significant, and the light transmittance of the film that is obtained as considering both reflection and absorption effects will increase greatly. According to the research, for a metallic silver film with a thickness smaller than 20 nm, the light transmittance of visible light increase greatly to 40% or higher.

However, if the cathode 206′ is directly configured as an extremely thin film, the square resistance of the cathode 206′ will be greatly increased. For example, when the cathode 206′ is a metal silver film with a thickness of 20 nm, the square resistance of the cathode 206′ is approximately 1Ω. Furthermore, considering factors such as an oxide layer on a surface of the cathode, discontinuous metal blocks caused by difficulty in uniformly and continuously covering of the extremely thin cathode, and further reduction of the thickness of the cathode on an uneven surface, an actual square resistance of the cathode 206′ will be 2-4Ω or greater.

For an OILED display array with a certain area, the cathode is required to bear a transient current that is great enough to stabilize a voltage difference between positive and negative electrodes of the light-emitting devices of millions of subpixels in the OLED display array. If the cathode 206′ has a great square resistance, a cathode signal on the cathode 206′ will be attenuated to a greater extent during the transmission process, resulting in non-uniform voltage drop across the entire image. As a result, an image displayed on the display panel will have quality deteriorations such as non-uniform brightness and color deviation. Moreover, the voltage drop in this OLED display array is closely related to the brightness of the displayed image. In particular, when the image displayed on the display panel is switched from a previous frame to a next frame, and spatial distribution of image brightness changes, it is more difficult to correct the image shadow and color deviation caused by the two-dimensional non-uniform voltage drop distributed on the displayed image.

In view of the above analysis, the light extraction capability of the display panel cannot be improved simply by thinning the entire cathode 206′, otherwise the square resistance of the cathode 206′ may be too high and thus other image quality degradation problems may occur.

Accordingly, an embodiment of the present disclosure provides a technical solution, which can reduce the luminous flux loss and improve the light extraction capability of the display panel while preventing the square resistance of the cathode from increasing significantly.

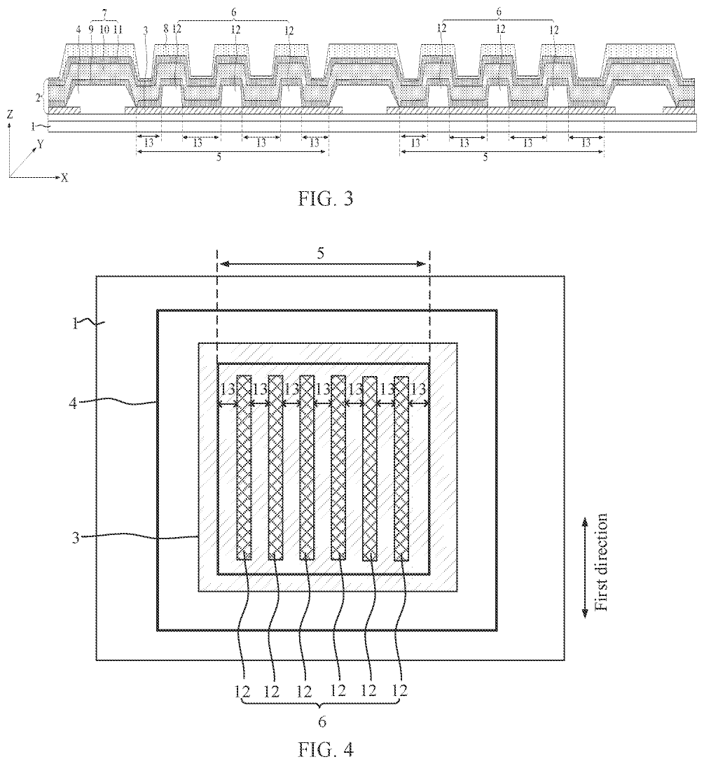

An embodiment of the present disclosure provides an organic light-emitting display panel, which can be applied to a micro display in the AR and VR. fields. FIG. 3 illustrates a sectional view of two adjacent subpixels in an X-Z plane of an OLED display panel according to an embodiment of the present disclosure. The OLED display panel includes a substrate I that may be a silicon wafer integrated with a pixel circuit, a row scan circuit, and a signal drive circuit.

A light-emitting device 2 is arranged on the substrate 1. The light-emitting device 2 includes: a first electrode 3, which is the anode described above and is electrically connected to a pixel circuit (not shown in the figure) integrated onto the substrate 1 to receive a drive current provided by the pixel circuit; a pixel definition layer 4 with a plurality of openings 5 arranged on the first electrode 3 facing away from the substrate 1, wherein; a fence structure 6 located in the plurality of openings 5 and facing away from the substrate 1; a light-emitting functional layer 7 arranged on the fence structure 6, and a part of the first electrode 3 within the plurality of openings 5 which is not covered by the fence structure; and a second electrode 8, i.e., the aforementioned cathode formed in sequence on the fence structure 6. As shown in FIG. 3, the light-emitting functional layer 7 may include a hole injection and transport layer 9, a light-emitting layer 10, and an electron injection and transport layer 11 stacked along a light-emitting direction of the OLED display panel. The injection and transport layer 9 may include two film layers, i.e., a hole injection layer and a hole transport layer. The electron injection and transport layer 11 may include two film layers, i.e., an electron injection layer and an electron transport layer. The light-emitting functional layer 7 may also include other layers, which will not be further described herein.

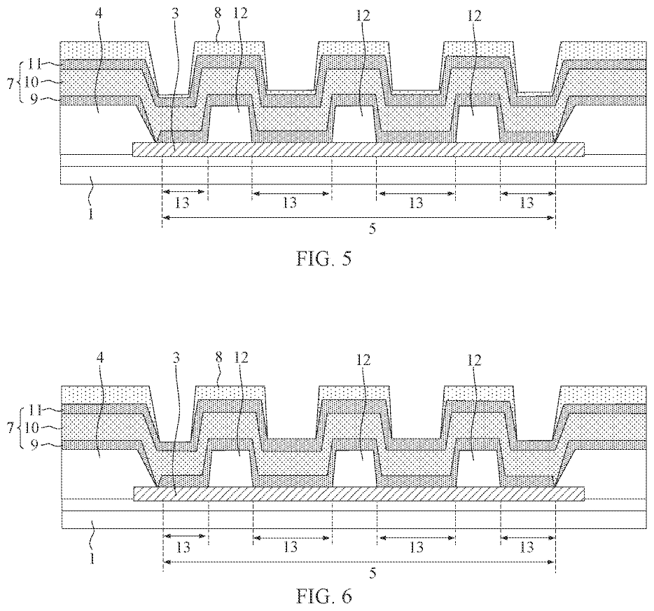

FIG. 4 illustrates a top view of a fence structure 6 in an opening 5 according to an embodiment of the present disclosure. FIG. 5 and FIG. 6 illustrate schematic views of a subpixel according to embodiments of the present disclosure, both indicating a thickness variation of the second electrode 8. As shown in FIG. 4 to FIG. 6, the fence structure 6 includes a plurality of fences 12 and trenches 13 arranged in parallel to the substrate 1. The trenches 13 parallel to the fences 12 are formed between the fence 12 and the pixel definition layer 4 or in spaces between two adjacent fences 12. The thickness of the second electrode 8 on the top of the fences 12 is larger than the thickness of the second electrode 8 between the fences 12.

Specifically, in an embodiment of the present disclosure, after the fence structure 6 is formed on the substrate 1, the hole injection and transport layer 9, the light-emitting layer 10, and the electron injection and transport layer 11 are sequentially formed on the substrate 1 by using a common vertical evaporation method. When forming any of the layers, an evaporation source containing a raw film material, such as a crucible or sputtering target, is configured to directly face the substrate 1. Flying trajectories of the atoms or molecules of the material emitted from the evaporation source have a large spatial angular distribution. Therefore, the layers formed by the evaporation are attached to surfaces of the fences 12 and the trenches 13, and fluctuate up and down along with the surfaces of the fences 12 and the trenches 13. With this evaporation method, the surface of the formed film is raised simultaneously with continuous deposition of the material on the top of each fence 12 and at a bottom of each of the trenches 13. The layers deposited in this region are relatively thick, and have an approximately same thickness. Further, the atoms or molecules of the material are deposited on the sidewall of the fences 12 and the side wall of the pixel definition layer 4 at a relatively large angle, so that the film thickness of the deposited layers is relatively small.

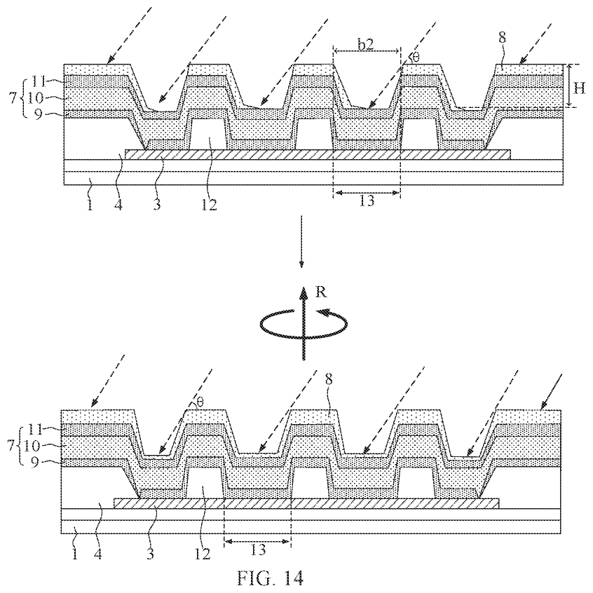

In combination with FIG. 14 to FIG. 16, after the light-emitting functional layer 7 is formed, the second electrode 8 is formed by an oblique evaporation process according to an embodiment of the present disclosure. During a process for forming the second electrode 8, the evaporation source contains a raw film material for forming the second electrode, such as the crucible or sputtering target, and the atoms or molecules emitted from the raw film material fly towards the substrate 1. A flying direction of the material is in an oblique angle θ with respect to the substrate 1. The oblique angle is defined as an evaporation angle θ in an embodiment of the present disclosure and is smaller than 90 degrees. In this evaporation method, the material flies obliquely to the substrate 1, such that the material is mainly deposited onto a part of the light-emitting function layer 7 on the tops of the fences 12 and the material of a certain thickness is also deposited onto another part of the light-emitting function layer 7 on the sidewall of the fences 12. However, since a part of the light-emitting function layer 7 at the bottom of the trenches 13 is covered with the fences 12, few material (or even no material) is deposited onto this part of the light-emitting function layer 7. As a result, the second electrode 8 has a smaller film thickness between the fences 12 than on the top of the fences 12. When no material is deposited in the spaces between two adjacent fences 12, the film thickness of the second electrode 8 in the spaces between two adjacent fences 12 is zero, which still meets the condition that the film thickness of the second electrode 8 on the top of the fences 12 is larger than the film thickness of the second electrode 8 between two adjacent fences 12. This evaporation process will be described in detail in embodiments of a manufacturing method hereinafter.

In this embodiment of the present disclosure, the film thickness of the part of the second electrode 8 between two adjacent fences is relatively small, so that this part of the second electrode 8 has less absorption in the light emitted from the light-emitting layer 10. In particular, when the film thickness of this part of the second electrode 8 is reduced to a certain extent, the optical properties of the nano film is presented, so that the light transmittance of this part of the second electrode 8 is increased. Accordingly, the second electrode 8 has a significant influence on the luminous flux of the light output from the display panel. Therefore, in this embodiment of the present disclosure, the loss of the overall luminous flux of the light output from the display panel can be significantly reduced by partially thinning a part of the second electrode 8. That is, the light output capacity of the display panel is improved. When an intensity of the light emitted from the display panel and carrying image information increases, the brightness of the image displayed on the display panel increases correspondingly, and the color gamut increases correspondingly, thereby optimizing the image quality.

Compared with the configuration in which an entire layer of the second electrode 8 is thinned, only the part of the second electrode 8 on the sidewall of the fences 12 and in the spaces between two adjacent fences is thinned partially according to some embodiments of the present disclosure. In this way, a square resistance of the second electrode 8 is slightly increased or remains consistent as compared with the existing display panel, thereby avoiding excessive signal voltage drop caused by significant increase of the square resistance, and thus avoiding obvious deterioration of the brightness uniformity and color display accuracy of the displayed image.

With further reference to FIG. 6, in this embodiment of the present disclosure, even if the film thickness of the second electrode 8 in the spaces between two adjacent fences 12 is zero, a potential of the electron injection and transport layer 11 in the spaces between two adjacent fences 12 is approximately equal to a potential of the second electrode 8 on the top of each fence 12 and on the sidewall of the fences 12 since the electrons can be diffused laterally in the electron injection and transport layer 11. In other words, the light-emitting devices can normally emit light under a sufficient bias voltage.

With further reference to FIG. 4, the fences of the plurality of fences 12 within each of the openings 5 are equally spaced and in parallel to each other. In addition, the fences 12 and the trenches 13 are interdigitally positioned, and therefore the trenches 13 between the fences 12 are also equally spaced and in parallel to each other. These evenly distributed fences and trenches lead to uniform light transmittance in the opening 5.

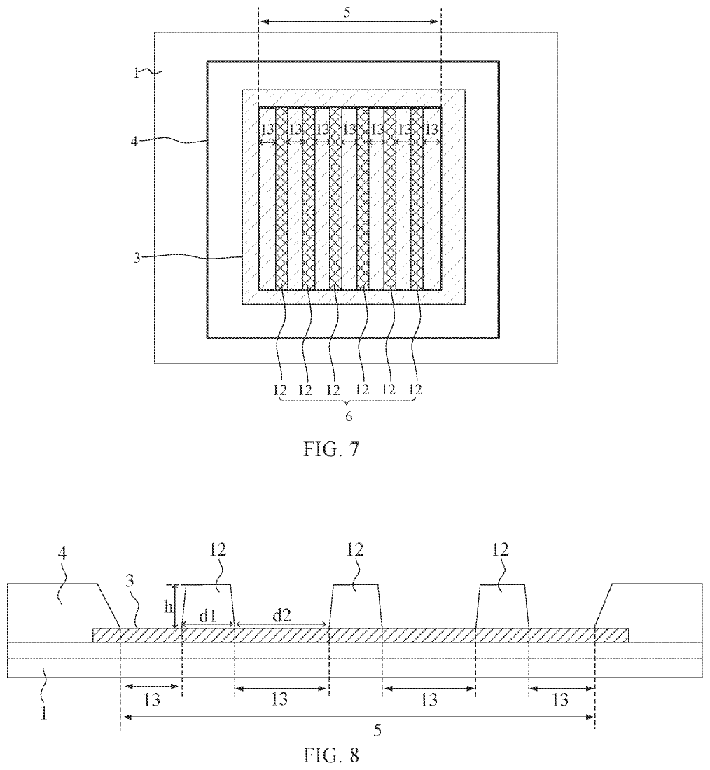

FIG. 7 illustrates a top view of another fence structure in an opening according to an embodiment of the present disclosure. As shown in FIG. 7, at least one end of the fence 12 is extended to the pixel definition layer 4, aiming to reducing surface bumping for any subsequently deposited films on the fence 12. More specifically, the second electrode 8 deposited above the top of the fence 12 is smoothly connected to the second electrode deposited on the top of the pixel definition layer 4 and therefore to the second electrode in the entire display region. This embodiment will ensure a continuous and uniform cathode bias voltage for all pixels across the entire display region.

FIG. 8 illustrates a sectional view of a fence structure. Light emitted in large angle from the sidewall of the fences or from the bottom of trenches may be blocked or absorbed by the materials on adjacent sidewalk, and consequently resulting in lower light output. To minimize these risks, the inventor has found that through simulations and analyses, the geometric dimensions of the fence and the trench may be designed the following way, as some embodiments of the present disclosure.

In an embodiment with reference to the sectional view in FIG. 8, a height h of the fence is defined as the vertical distance from the upper surface of the first electrode 3 to the top surface of the fence 12, and a thickness di of the fence is defined as a thickness at the half height of the fence in a direction perpendicular to a surface of the sidewall of the fence. The height to the thickness ratio satisfies the equation 0.5≤h/d1≤2.

In another embodiment with further reference to FIG. 8, the fences and the trenches are periodically and interdigitally arranged on a plane in parallel to the substrate 1, resulting in a periodically repeated up-and-down surface topology. A duty ratio of the surface topology is defined as d1/(d1+d2), where d2 is a trench width, defined as a spatial distance between every two adjacent fences 12. in some embodiments, the duty ratio satisfies an equation 0.3≤d1/(d1+d2)≤0.75.

In another embodiment, still with reference to FIG. 8, a depth to width ratio of the trenches is defined as h/d2, which satisfies an equation 0.5≤h/d2≤2.

In compliance with specific display application and performance specifications, the geometric factors of the fence and the trench may be selected according to the above embodiments. To implement an OLED deposition process, including deposition and pattering of multiple organic films and metal electrodes, engineers should combine both the geometric factors of the substrate surface topology and hardware settings in the vapor deposition chamber, including position and angle of the evaporation sources respect to the display substrate.

In an embodiment, both the thickness d1 of the fence and the trench width d2 may be smaller than or equal to 100 nm. In this case, the geometric dimension of the fence structure 6 enters into an nanometer scale, which is significantly less than a wavelength of the light emitted from the OLED film, and more importantly the nanometer scale structure is a periodically repeated pattern. Films conformally covered the fences 12 will exhibit a similar nanometer-scale periodically repeated pattern. Some special effects originated from the nanostructure may be developed accordingly, such as greatly reduced optical reflections on the surface of the films. Therefore, more light can be extracted from the OLED film, and thereby effectively increasing the light output. Since a micro-OLED display is generally made on a silicon wafer, nanometer scale patterning for the fence structure is quite feasible by using existing lithography process technology.

After the second electrode 8 is formed, a planarization layer is covered on the second electrode 8 to achieve planarization of the film. If the planarization layer is directly formed on the second electrode 8, a part of water and oxygen may permeate into the display panel through the second electrode 8 during a process of forming the planarization layer to invade the light-emitting layer 10, causing luminescence quenching, and in turn causing black spots or dark areas occurring on the display panel due to emission failure or severe luminescence attenuation. As moisture and oxygen molecules gradually diffuse laterally to other light-emitting device nearby, the dark areas gradually expand, resulting in a fatal influence on the display effect In particular, the part of the second electrode S on the sidewall of the fences 12 and in the spaces between two adjacent fences is much thinner than the part of the second electrode 8 on the top of each of the fences 12, and even the part of the second electrode 8 in the spaces between two adjacent fences has a film thickness of zero. Therefore, moisture and oxygen molecules is prone to permeating through this region.

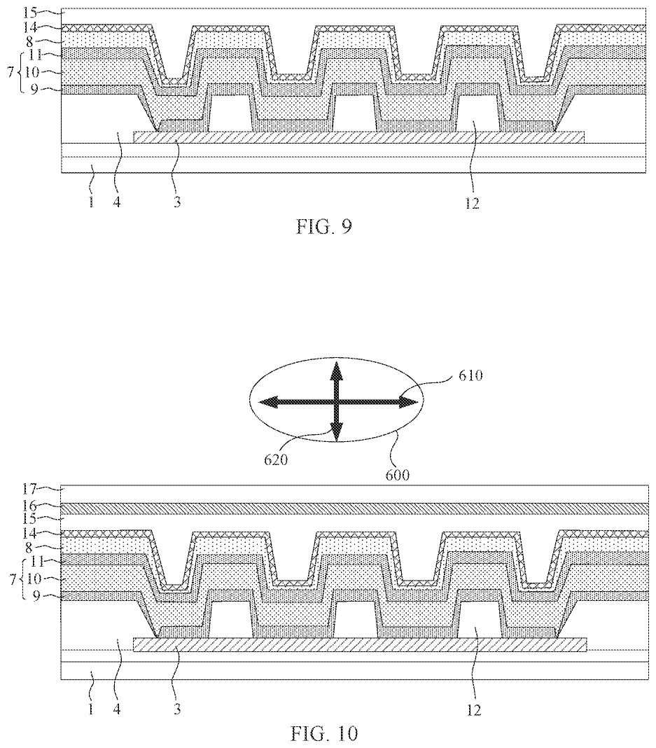

FIG. 9 illustrates a sectional view of an encapsulated subpixel according to an embodiment of the present disclosure. Referring to FIG. 9, an encapsulation protection layer 14 with higher airtightness is provided on a side of the second electrode S facing away from the substrate 1. The encapsulation protection layer 14 may be a layer formed by alternately stacking silicon oxide and silicon nitride, so as to effectively isolate water and oxygen. When a planarization layer 15 is further formed on the encapsulation protection layer 14 subsequently, penetration of the moisture and oxygen molecules can be prevented, even in a process of coating an organic film containing a chemical solvent and baking and curing the organic film.

It should be noted that after the hole injection and transport layer 9, the light-emitting layer 10, and the electron injection and transport layer 11 are sequentially stacked on the fences 12, this part of the light-emitting layer is recessed at the bottoms of the trenches 13 and substantially fill all the trenches 13. When the dimension of the fence 12 reaches the nanometer level, in the direction perpendicular to the extending direction of the fences 12, the surface fluctuation of this part of the light-emitting layer is much smaller than the wavelength of the light emitted from the light-emitting devices. Even when the dimension of the fence 12 is equal to or smaller than 100 nm, a special effect of a nanometer surface can be achieved. In particular, in the direction perpendicular to the extending direction of the fences 12, an effective refractive index of the multiple layers is a combined effect of the optical properties of all these layers. However, in this case, reflection or refraction between the layers will not be effective, at least no longer affecting the light transmittance.

Considering that a light wave, as an electromagnetic wave, has two electric vectors perpendicular to each other in a direction perpendicular to a propagation direction thereof, the anisotropy of the optical properties in the X-Y plane will cause the light wave of the light emitted from the light-emitting devices to have certain polarization property. With further reference to FIG. 4, the extending direction of the fences 12 in this embodiment of the present disclosure is the first direction, the second electrode 8 has little influence on the electromagnetic wave oscillation in a direction perpendicular to the first direction since the material of the second electrode 8 absorbs the electromagnetic wave and strong reflection is occurred respectively on an upper and lower interfaces of the second electrode 8. In this embodiment of the present disclosure, when both the thickness of the fence and the trench width are smaller than or equal to half of the wavelength of the light emitted from the light-emitting devices, or smaller than or equal to 100 nm, the optical properties of the film will have essential change due to the fluctuation structure of the light-emitting layer formed by covering the fences 12. In this case, the light emitted from the light-emitting layer will present a property similar to elliptically polarized light, that is, an electromagnetic wave vibration vector in a certain direction is greater than an electromagnetic wave vector in another direction perpendicular to this certain direction. Specifically, the electromagnetic wave vector parallel to the extending direction of the fences is less than the electromagnetic wave vector perpendicular to the extending direction of the fences.

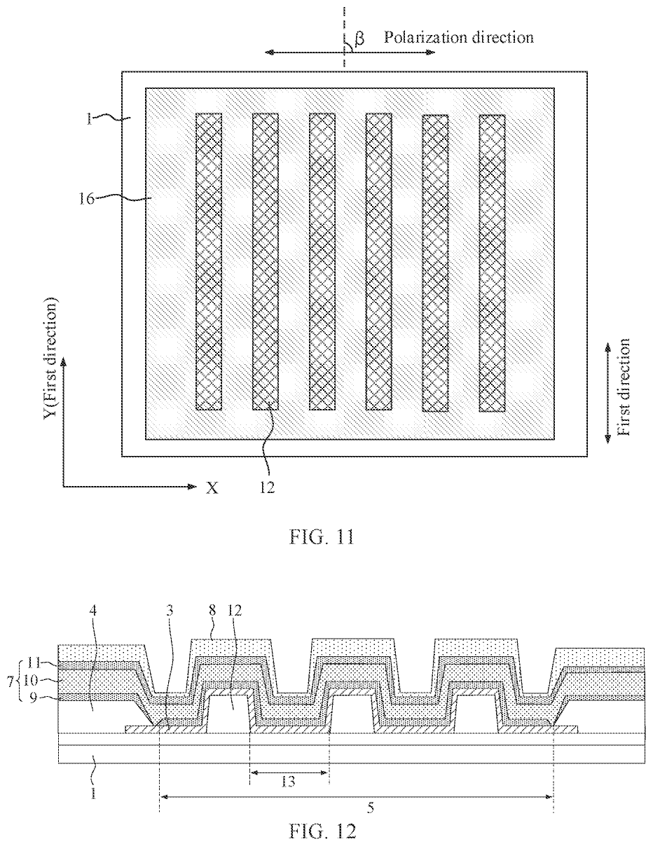

FIG. 10 illustrates a sectional viewing indicating a polarization direction of a polarizer 16 according to an embodiment of the present disclosure. FIG. 11 illustrates a top plane view indicating a polarization direction of a polarizer 16 according to an embodiment of the present disclosure. As shown in FIG. 10 and FIG. 11, the organic light-emitting display panel further includes a polarizer 16 laminated on the second electrode S. The polarization direction of the polarizer 16 and the length direction of the fences 12 form an angle between 75 degrees and 105 degrees, for example, is 90°. FIG. 10 illustrates an elliptically polarized light indicated by 600, in which 610 represents an X electric field vector of the emitted light and 620 represents a Y electric field vector of the emitted light. Only the light that is polarized in a direction nearly perpendicular to the extending direction of the fences can be emitted with reference to the polarization direction of the polarizer 16. However, the light perpendicular to the polarization direction or internal scattered, refracted or stray light will be blocked and cannot be emitted, thereby increasing the contrast of the displayed image.

Specifically, as shown in FIG. 10, the polarizer 16 may be arranged between the planarization layer 15 and a cover 17, or the polarizer 16 may be arranged on a side of the cover 17 facing away from the substrate Fin an embodiment of the present disclosure, the cover 17 may be reused as the polarizer 16 by directly patterning, on the cover 17, a stripe array having a dimension of nanometer scale and parallel to the extending direction of the fences 12.

In an embodiment, the fence structure 6 is made of an insulation material. For example, the fence structure 6 may be an inorganic film such as silicon nitride, or the fence structure 6 may include protrusions formed by an organic material and a silicon oxide film or silicon nitride film covering the protrusions to isolate water and oxygen. Since an etching rate of the insulating material is significantly different from an etching rate of a metal material or metal oxide material for forming the first electrode 3, that is, the etching options are within a relatively large range, the fence structure 6 is made of an insulation material. Therefore, when the fence structure 6 is disposed on a side of the first electrode 3 facing away from the substrate 1, the patterning of the fence structure 6 becomes easier.

In addition, even if the fence structure 6 is disposed in the openings 5 and faces away from the substrate 1 in a manner that the hole injection and transport layer 9 located on the tops and on the sidewalls of the fences 12 cannot directly obtain a potential of the first electrode 3, the potential of the hole injection and transport layer 9 located on the tops and on the sidewalls of the fences 12 can be consistent to the potential of the first electrode 3 since holes diffuse laterally in the hole injection and transport layer 9.

In an embodiment, the fence structure 6 may also be made of a conductive material. For example, the fence structure 6 may be made of a semiconductor material such as a silicon material, or the fence structure 6 may be made of a metal material with higher conductivity, or the fence structure 6 may be made of a metal oxide material with certain conductivity. In this case, even when the fence structure 6 is disposed on the side of the first electrode 3 facing away from the substrate 1, the potential of the first electrode 3 can be directly applied to the hole injection and transport layer 9 located on the tops and on the sidewalk of the fences 12 through the conductive fences 12, thereby performing an electrical or chemical action on this part of the hole injection and transport layer 9.

In an embodiment, with further reference to FIG. 5, the fence structure 6 is located between the first electrode 3 and the light-emitting functional layer 7. In this case, the first electrode 3 has a flat surface and uniform thickness, and does not have surface fluctuation caused by the fences 12, thereby avoiding increase in the square resistance caused by thinning the film located on the sidewalls of the fences 12.

Furthermore, the fences 12 and the pixel definition layer 4 may be made of the same material in the same process. In this way, the fences 12 are formed without an additional process, thereby reducing a coating process and a photolithographic process for forming the fences 12 and thus simplifying the manufacturing process. In this case, the height of the fence is substantially the same as the thickness of the pixel definition layer 4.

FIG. 12 illustrates a sectional view of another fence structure according to an embodiment of the present disclosure. Referring to FIG. 12, the fence structure 6 is located between the first electrode 3 and the substrate 1. In this case, the first electrode 3 is configured to be always in direct contact with the hole injection and transport layer 9 in the opening 5, such that the tops of the fences 12, the sidewall of the fences 12, and the hole injection and transport layer 9 located at the bottoms of the trenches 13 can directly obtain all voltages provided by the first electrode 3. Compared to a case that the potential of the entire hole injection and transport layer 9 is maintained by lateral diffusion of the holes, the fence structure in this embodiment can avoid a relatively low bias voltage caused by the small film thickness or hole mobility of the hole injection and transport layer 9, otherwise which may lead to decrease in luminous intensity.

An embodiment of the present disclosure further provides a method for manufacturing an organic light-emitting display panel. With reference to FIG. 14 to FIG. 17, the manufacturing method includes: positioning the substrate 1 overlaid by the first electrode, the pixel definition layer and the fence structure on a supporting stage inside a vapor deposition chamber; providing at least one evaporation source, such as a crucible or a sputtering target, containing a raw material for forming a second electrode in the vapor deposition chamber; forming the second electrode 8 on the substrate 1 by heating the crucible or by plasma bombarding the sputtering target; and arranging the substrate 1 and the crucible or sputtering target in a manner that the majority of the raw material flying from the crucible or the sputtering target land on the substrate 1 in an oblique angle which is substantially smaller than 90 degrees.

With the above manufacturing method, a part of the second electrode 8 formed on the sidewall of the fences 12 and in the spaces between two adjacent fences 12 can be thinner, thereby increasing the light transmittance of this part of the second electrode 8 and thus reducing the loss of the overall output luminous flux of the display panel. Moreover, only the part of the second electrode 8 on the sidewall of the fences 12 in the spaces between two adjacent fences 12 is thinned, so that the square resistance of the second electrode 8 will be only slightly increased or remain unchanged compared to the case in the prior art, thereby avoiding the problem of excessive signal voltage drop caused by large increase in the square resistance.

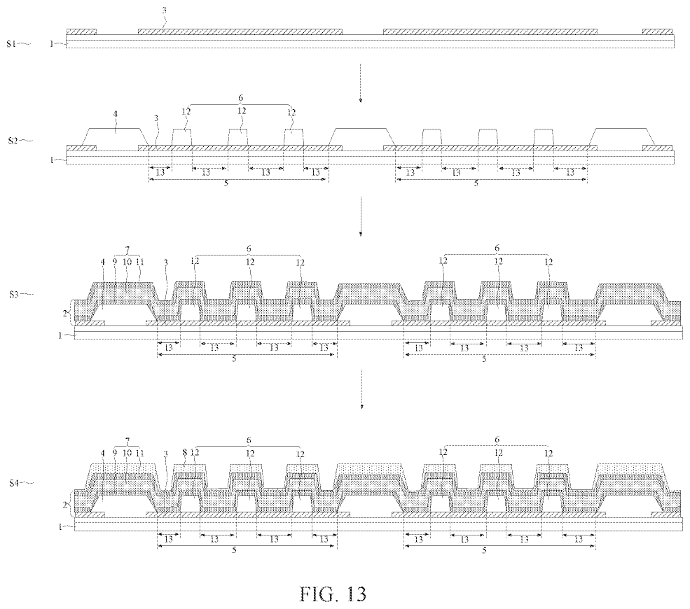

For example, the fence structure 6 may be located in the openings 5 and faces away from the substrate 1. In this case, a process for manufacturing a display panel will be described with reference to a flowchart of the manufacturing process of the OLED display panel in FIG. 13.

At step S1, a plurality of individual first electrodes 3 is formed on the substrate 1 by using magnetron sputtering or high-temperature vapor deposition. In this step, the first electrodes 3 may be made of a material selected from metal or metal oxide with a relatively high work function, such as indium tin oxide ITO), so that a part of the light emitted from the light-emitting layer 10 towards the substrate 1 can be efficiently reflected in a light top-emitting device. In an embodiment, the first electrodes 3 may be formed into a sandwich structure of ITO-Ag-ITC) and a reflection effect is performed by a silver film in the sandwich structure.

At Step S2, the fence structure 6 and the pixel definition layer 4 are formed, the material for forming the fences 12 and the dimensions of the fences 12 and the trenches 13 have been described in detail in the above embodiments, and will not be repeated herein.

At Step S3, the hole injection and transport layer 9, the light-emitting layer 10 and the electron injection and transport layer 11 are sequentially formed by vapor deposition. Specifically, when forming any of the above layers, a side of the substrate 1 for depositing the layer faces downwards, the crucible or sputtering target containing the raw material for forming the layer is placed below the substrate l to directly face towards the substrate 1, and the atoms or molecules of the material emitted from the crucible or sputtering target upwardly fly towards the substrate 1 and are then attached to the substrate 1. In this case, the films deposited on the tops of the fences 12, at the bottoms of the trenches 13 and on the top of the pixel definition layer 4 have relatively large thicknesses that are equal to each other, while the film deposited on the sidewall of the fences 12 and the film deposited on the side wall of the pixel definition layer 4 have a relatively small film thickness. A ratio of the film thickness of the film deposited between the fences 12 to the film thickness of the film deposited on the top of the fences 12 varies based on a tilted angle of the sidewall of the fences 12.

At step S4, the second electrode 8 is formed by the above oblique vapor deposition process, which will not be repeated herein.

FIG. 14 illustrates an oblique vapor deposition process by rotating the substrate supporting stage according to an embodiment of the present disclosure. n an embodiment, as shown in FIG. 14, the film forming process of the second electrode 8 includes a first half time and a second half time, each of which has substantially equal duration. During the first half time, the atoms or molecules of the material emitted from the evaporation source such as the crucible or sputtering target fly towards the substrate 1 at a vapor deposition angle θ so as to perform the vapor deposition on one side of the substrate 1. After a part of the substrate 1 with half of the thickness is performed by vapor deposition, during the second half time, the supporting stage rotates 180 degrees on the stage plane between the first half time and the second half time, while the evaporation source is stationary and the atoms or molecules of the material emitted from the evaporation source continue to fly towards the substrate 1 at the vapor deposition angle θ, so as to perform vapor deposition on another side of the substrate 1.

It should be noted that the above embodiments are the illustrative embodiments, in which the film forming process of the second electrode 8 includes only the first half time and the second half time. However, in actual operation, the vapor deposition process may also be performed by circulating the first half time and the second half time during the film forming process of the second electrode 8, as long as the second electrode 8 having a desired thickness is deposited.

FIG. 15 illustrates another oblique vapor deposition process according to an embodiment of the present disclosure. In an embodiment, as shown in FIG. 15, the film forming process of the second electrode B includes the first half time and the second half time, each of which has the same duration. During the first half time, the atoms or molecules of the material emitted from the evaporation source fly towards the substrate 1 at a vapor deposition angle θ, so as to perform the vapor deposition on one side of the substrate 1. During the second half time, after the evaporation source rotates to another side of the substrate 1 opposite to the one side, the atoms or molecules of the material emitted from the evaporation source fly towards the substrate 1 at a vapor deposition angle −θ so as to continue to perform the vapor deposition on the another side of the substrate 1. This vapor deposition method only moves the evaporation source without rotating the array substrate 1, thereby preventing the substrate 1 from affecting the film formed thereon during the rotation.

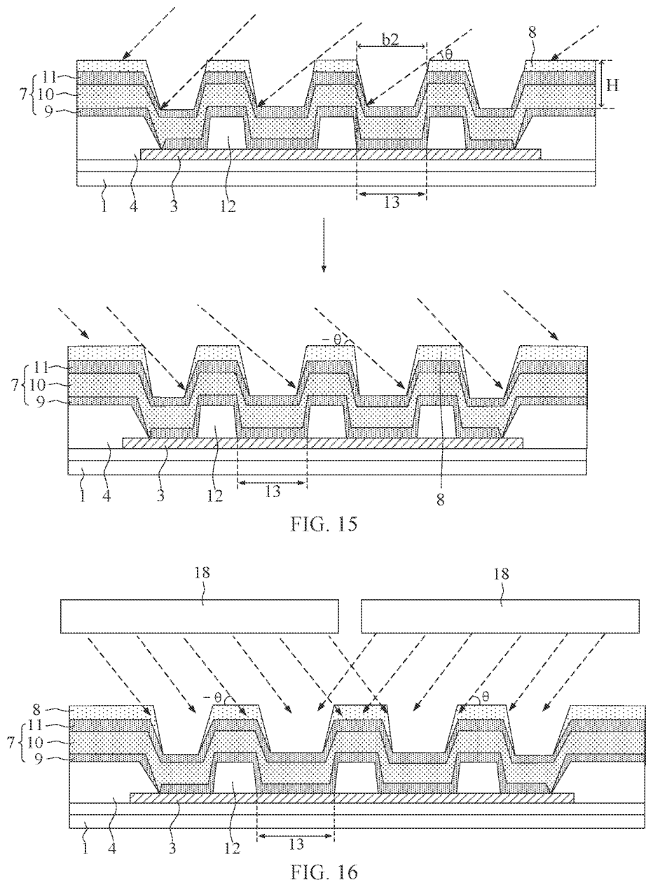

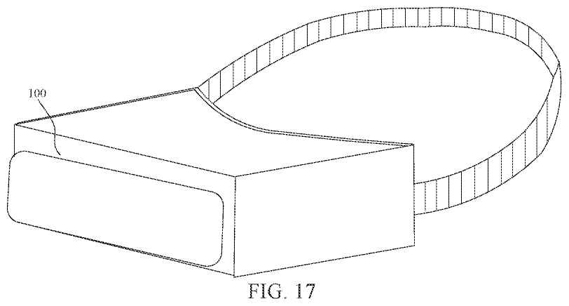

FIG. 16 illustrates a set-up of yet another oblique vapor deposition process according to an embodiment of the present disclosure. In an embodiment, as shown in FIG. 16, two evaporation sources 18 containing a raw material for forming the second electrode, such as two crucibles or two sputtering targets, are located opposite with respect to the center of the substrate in the vapor deposition chamber. The raw material from the two crucibles or two sputtering targets are deposited on the substrate 1 simultaneously. Moreover, the atoms or molecules of the material emitted from one of the two evaporation sources 18 fly towards the substrate 1 at the vapor deposition angle θ, and the other one of the two evaporation sources 18 fly towards the substrate 1 at the vapor deposition angle −θ. In this vapor deposition method, the two evaporation sources 18 are used to simultaneously perform the vapor deposition, thereby saving the time of the vapor deposition and preventing the substrate 1 from performing mechanical movement during the vapor deposition process.

In an embodiment, the supporting stage rotates continuously at a constant speed during the film forming process of the second electrode 8, wherein the straight line is the central axis. The atoms or molecules of the material emitted from the evaporation sources fly towards the substrate 1 during the rotation, so as to form the second electrode 8. This vapor deposition method is required to only control the substrate 1 to continuously rotate during the film forming process, and it is unnecessary moving the evaporation sources or adjusting the orientation of the substrate 1 during the vapor deposition, and the operation thereof is more convenient.

Compared with the two previous vapor deposition methods, in this evaporation method, the atoms or molecules of the material emitted from the evaporation sources are deposited at the bottoms of the trenches 13 along the extending direction of the trenches 13 within a short period, thereby increasing the thickness of the film deposited at the bottoms of the trenches 13. However, the film thickness of the second electrode 8 at the bottoms of the trenches 13 is still much greater than the film thickness of the second electrode S on the top of the fences 12.

In addition, compared to vertical vapor deposition in a case that the vapor deposition angle θ is equal to 90°, the layer film thickness of the film deposited between the fences 12 in a case that the vapor deposition angle θ is smaller than 90° is required to be greater than the film thickness of the film deposited between the fences 12 in a case that the vapor deposition angle θ is equal to 90°, or the film thickness of the film deposited between the fences 12 is even greater than the film thickness of the film deposited on the top of the fences 12. It should be noted that the film thickness of the deposited film can be adjusted as actual requirements.

In the vapor deposition method shown in FIG. 14, the vapor deposition angle θ satisfies tan θ≤2H/d2, where d2 denotes the trench width of the trench 13 in a direction perpendicular to an extending direction of the trench 13, and H denotes a relative height of the second electrode 8 from the bottom of the trench. During the first half time, the material is only deposited in a small region at the bottom of each trench 13, but no material is deposited in the remaining region at the bottom of the trench 13 in an ideal condition. After that, during the second half time, the supporting stage rotates 180 degrees, then the material is deposited in the remaining region at the bottom of the trench 13. Finally, the film thickness of the second electrode 8 at the bottoms of the trenches 13 is smaller than or equal to half of the film thickness of the second electrode 8 on the top of the fences 12.

With reference to FIG. 14, if the vapor deposition angle θ satisfies tan θ≤H/d2, no material is deposited at the bottoms of the trenches 13 in an ideal condition such that the film thickness of the second electrode 8 deposited at the bottoms of the trenches 13 shall be zero.

It should be noted that in an actual vapor deposition process, the flying trajectories of the material particles emitted from the evaporation source are not parallel to each other. When the material particles hit a surface of the device with a certain momentum, the material particles may be ejected and scattered, thereby changing a final deposition position. Therefore, the above embodiment, in which no material is deposited at the bottoms of the trenches 13, is only an ideal situation. In fact, a small amount of material may be deposited at the bottoms of the trenches 13, and the small amount of material is more likely to be deposited at the bottoms of the trenches 13 in a scattered manner, which hardly forms a continuous thin film with a certain thickness.

In view of the above, a geometric dimension of the light-emitting device, parameters of the vapor deposition process and the light-emitting performance of the light-emitting device are correlated. Accordingly, the vapor deposition angle may satisfy a condition of H/d2<tan θ≤(2×H)/d2, such that the film thickness of the film of the second electrode 8 deposited at the bottoms of the trenches 13 is significantly less than the film thickness of the film of the second electrode 8 deposited on the top of the fences 12, thereby outputting a relatively high luminous flux from the bottoms of the trenches 13.

In addition, when the vapor deposition angle θ is smaller than 90 degrees, a part of the evaporated material is directly deposited at a wall of the vapor deposition chamber. If the vapor deposition angle θ is too small, more materials will fly towards the wall of the vapor deposition chamber, resulting in material waste and long vapor deposition time. Therefore, in an actual vapor deposition process, the vapor deposition angle θ may be configured to be greater than or equal to 15 degrees, so as to reduce material waste and reduce the production cost.

An embodiment of the present disclosure also provides an organic light-emitting display device. FIG. 17 illustrates a schematic diagram of a structure of a VR glass system using the OLED device according to an embodiment of the present disclosure. As shown in FIG. 17, the organic light-emitting display device includes the organic light-emitting display panel 100 as described above. A specific structure of the organic light-emitting display panel has been described in detail in the aforementioned embodiments, and will not be repeated herein. The organic light-emitting display device shown in FIG. 17 is a glasses device applied in the field of augmented reality and virtual reality. It should be understood that the organic light-emitting display device may also be a display device of other type.

It should be noted that, the above embodiments are merely for illustrating technical solutions of the present disclosure, but not intended to provide any limitation. Although the present disclosure has been described in detail with reference to the above embodiments, it should be understood that it is still possible for those skilled in the art to modify the technical solutions described in the above embodiments or to equivalently replace some or all of the technical features therein, without departing from the essence of corresponding technical solutions of the present disclosure.

What is claimed is:

1. An organic light-emitting display panel, comprising:
a substrate; and
a light-emitting device disposed on the substrate, the light-emitting device comprising:
a first electrode;
a pixel definition layer with a plurality of openings located on the first electrode facing away from the substrate;
a fence structure located in the plurality of openings and facing away from the substrate;
a light-emitting functional layer; and
a second electrode formed in sequence on the fence structure;
wherein the fence structure comprises a plurality of fences and trenches arranged in parallel to the substrate, and
the thickness of the second electrode on the top of the fences is larger than the thickness of the second electrode between the fences.

2. The organic light-emitting display panel according to claim 1, wherein the fences of the plurality of fences within each of the plurality of openings are arranged equally spaced and in parallel to each other, and the fences and the trenches are interdigitally positioned.

3. The organic light-emitting display panel according to claim 1, wherein at least one end of each of the plurality of fences is connected to the pixel definition layer.

4. The organic light-emitting display panel according to claim 1, wherein the fence structure is defined by the equation 0.5≤h/d1≤2, where h is the height of the fence, d1 is the thickness of the fence.

5. The organic light-emitting display panel according to claim 1, wherein the fence structure is defined by the equation 0.3≤d1/(d1+d2)≤0.75, where d1 is the thickness of the fence, d2 is a spatial distance between two adjacent fences.

6. The organic light-emitting display panel according to claim 1, wherein the fence structure is defined by the equation 0.5≤h/d2≤2, where h is the height of the fence, d2 is the trench width that is a spatial distance between two adjacent fences.

7. The organic light-emitting display panel according to claim 1, wherein both the thickness d1 of the fence and the trench width d2 are smaller than or equal to 100 nm.

8. The organic light-emitting display panel according to claim 2, further comprising:
a polarizer laminated on the second electrode, wherein the polarization direction of the polarizer and the length direction of the fences form an angle between 75 degrees and 105 degrees.

9. The organic light-emitting display panel according to claim 1, wherein the fence structure is made of an insulation material.

10. The organic light-emitting display panel according to claim 1, wherein the fence structure is made of a conductive material.

11. The organic light-emitting display panel according to claim 1, wherein the fence structure is located between the first electrode and the light-emitting functional layer.

12. The organic light-emitting display panel according to claim 1, wherein the fence structure is located between the first electrode and the substrate.

13. A method for manufacturing the organic light-emitting display panel according to claim 1, comprising:
positioning the substrate overlaid by the first electrode, the pixel definition layer and the fence structure on a supporting stage inside a vapor deposition chamber;
providing at least one crucible or sputtering target containing a raw material for forming the second electrode in the vapor deposition chamber;
forming the second electrode on the substrate by heating the crucible or by plasma. bombarding the sputtering target; and
arranging the substrate and the crucible or sputtering target in a manner that the majority of the raw material flying from the crucible or the sputtering target land on the substrate in an oblique angle which is substantially smaller than 90 degrees.

14. The method according to claim 13, wherein said forming process of the second electrode includes a first half time and a second half time, each of which has substantially equal duration, the supporting stage rotates 180 degrees on the stage plane between the first half time and the second half time.

15. The method according to claim 13, wherein two crucibles or two sputtering targets containing the raw material for forming the second electrode are located opposite with respect to the center of the substrate in the vapor deposition chamber; and
the raw material from the two crucibles or two sputtering targets are deposited on the substrate simultaneously.

16. The method according to claim 13, wherein said forming the second electrode comprises an operation of rotating the supporting stage continuously at a constant speed.
